(19) United States
(12) Patent Application Publication
(10) Pub. No.: US 2026/0065997 A1
(43) Pub. Date: Mar. 5, 2026

(54) MEMORY STRUCTURE WITH SECURE GLOBAL ERASE

(71) Applicant: Sandisk Technologies, Inc., Milpitas, CA (US)

(72) Inventor: Daniel Bedau, San Jose, CA (US)

(73) Assignee: Sandisk Technologies, Inc., Milpitas, CA (US)

(21) Appl. No.: 18/824,397

(22) Filed: Sep. 4, 2024

(51) Int. Cl. G11C 16/14; G11C 5/06; G11C 16/04; H10B 41/10; H10B 41/20; H10B 41/35; H10B 43/10; H10B 43/20; H10B 43/35

(52) U.S. Cl. CPC G11C 16/14; G11C 5/06; G11C 16/0483; H10B 41/10; H10B 41/20; H10B 41/35; H10B 43/10; H10B 43/20; H10B 43/35

(57) ABSTRACT

A memory structure is located on a substrate. The memory structure includes electrically conductive lines connected to memory cells with electrically insulating material between the electrically conductive lines. The memory structure further includes an energy-release material in at least one of the electrically conductive lines, the memory cells, the electrically insulating material or the substrate.

### BACKGROUND

The present technology relates to memory structures including nonvolatile memory structures and methods for irreversibly erasing memory structures.

Semiconductor memory is widely used in various electronic devices such as cellular telephones, digital cameras, personal digital assistants, medical electronics, mobile computing devices, non-mobile computing devices and data servers. Semiconductor memory may comprise nonvolatile memory or volatile memory. A nonvolatile memory allows information to be stored and retained even when the nonvolatile memory is not connected to a source of power (e.g., a battery). Examples of nonvolatile memory include flash memory (e.g., NAND-type and NOR-type flash memory), Electrically Erasable Programmable Read-Only Memory (EEPROM), and others. In NAND memory, memory cells are connected in series to form NAND strings.

When a data storage system that includes nonvolatile memory is deployed in or connected to an electronic device (the host), the memory system can be used to store data and read data. For example, data may be stored in response to a program (write) command. Data may be read in response to a read command. Data may also be erased in response to an erase command. In some examples, a portion of a memory structure (e.g., a block) is erased by an erase operation directed to that portion (e.g., a selected block). An erase operation may include applying appropriate voltage(s) to components of the selected portion (e.g., word lines, bit lines). In some cases, it may be desirable to erase all data in a memory device (e.g., memory die, package or other such unit). For example, for security purposes, it may be desirable to erase all stored data in response to certain triggering events to avoid unauthorized accessing of stored data. Implementing such a global erase in a secure, safe manner presents various challenges.

### BRIEF DESCRIPTION OF THE DRAWINGS

Like-numbered elements refer to common components in the different Figures.

FIG. 1 is a block diagram depicting one embodiment of a storage system.

FIG. 2A is a block diagram of one embodiment of a memory die.

FIG. 2B is a block diagram of an example of an integrated memory assembly.

FIG. 3 shows an example of a portion of a memory structure.

FIGS. 4A-C illustrate an example of a NAND memory structure.

FIGS. 5A-D illustrate an example of a cross-point memory structure.

FIG. 6 illustrates an example of a memory cell.

FIGS. 7A-B illustrate examples of energy-release material in a conductive line of a memory structure.

FIGS. 8A-B illustrate examples of energy-release material in the insulating material of a memory structure and in the substrate.

FIGS. 9A-B illustrate an example of energy-release material in memory cells of a memory structure.

FIGS. 10A-B illustrate examples of energy-release initiators.

FIG. 11 illustrates an arrangement that includes a trigger circuit connected to an energy-release initiator.

FIG. 12 illustrates an example of a package that includes a visible erase-indicator to indicate when erase has occurred.

FIG. 13 illustrates an example of a method that includes forming memory cells on a substrate and depositing an energy-release material over the substrate.

### DETAILED DESCRIPTION

Techniques are disclosed herein to enable data stored in a memory structure to be securely, safely and rapidly erased. In some memory structures, data is stored by changing a physical characteristic of a portion of data storage material (e.g., changing electrical charge in a charge-trapping material, changing phase of a phase change material, changing resistance of a resistive material or changing magnetic properties of a magnetic material). In some cases, temperature above some threshold temperature may change a physical characteristic of a data storage material to cause the stored data to become unrecoverable (e.g., changing electrical charge, phase, resistance, magnetic properties and/or other physical characteristic). High temperature may also affect conductive lines, dielectric material and/or other components to make stored data inaccessible. Raising the temperature of a memory structure to a sufficient temperature may erase all data in the memory structure, which may provide a high degree of security for any stored data.

Aspects of the present technology are directed to technical problems associated with securely, safely and rapidly erasing data stored in a memory structure. Technical solutions include locating one or more portions of energy-release material (e.g., thermite, nano-thermite, thermate, metallic multi-layer material or other materials that can produce an exothermic reaction to generate heat) in or near a memory structure. When initiated, such materials produce significant heat. Locating such material close to or in the memory structure ensures that heat generated is effective in erasing memory cells and/or damaging other memory structure components (e.g., conductive lines and/or dielectric). Heat may be substantially confined to a memory structure so that there is little or no risk of damage to surroundings (e.g., little or no risk of fire or explosion).

Energy-release material may form at least part of one or more conductive lines of a memory structure, may form at least part of one or more memory cells of a memory structure and/or may be located in a substrate under a memory structure or a dielectric between conductive lines of a memory structure. Energy-release material may be deposited on a substrate during die fabrication using techniques that are compatible with memory structure fabrication (e.g., sputtering alternating layers of materials from different sputtering targets to form a metal multi-layer structure).

A visible erase-indicator that a memory die is erased or destroyed may be provided by a heat-activated erase-indicator located in an appropriate location (e.g., on the outside of a die or die package).

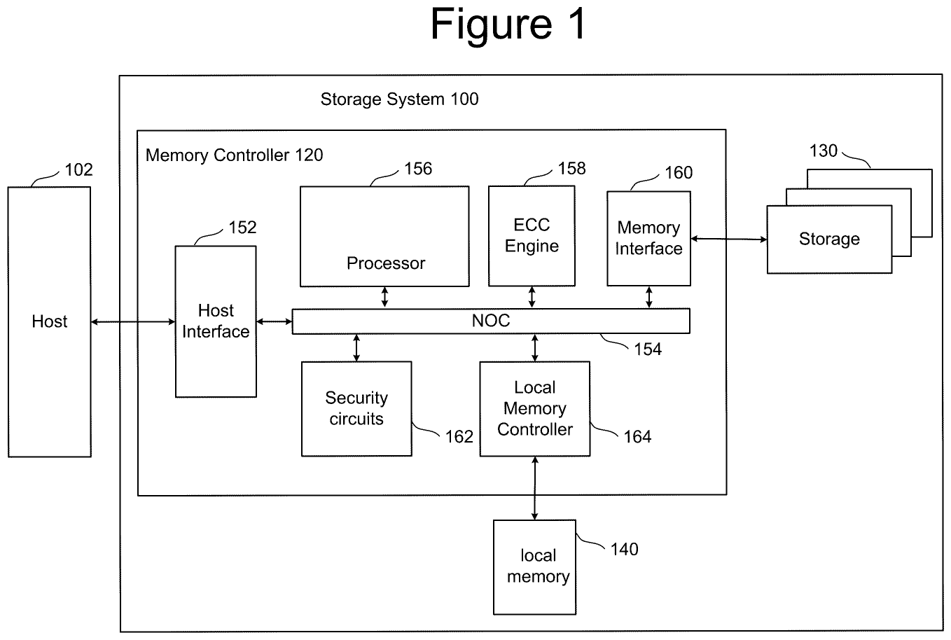

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to nonvolatile storage 130 and local high speed memory 140 (e.g., DRAM, SRAM, MRAM). Local memory 140 is non-transitory memory, which may include volatile memory or nonvolatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus.

Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the nonvolatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die.

Memory interface 160 communicates with nonvolatile storage 130. In one embodiment, memory interface provides a Toggle Mode interface. Other interfaces can also be used. In some example implementations, memory interface 160 (or another portion of memory controller 120) implements a scheduler and buffer for transmitting data to and receiving data from one or more memory die.

Security circuits 162 may control access to nonvolatile storage 130. For example, security circuits 162 may implement password protection, digital rights management or other protection of data stored in nonvolatile storage 130 so that only authorized users may access (read, write or erase) storage 130.

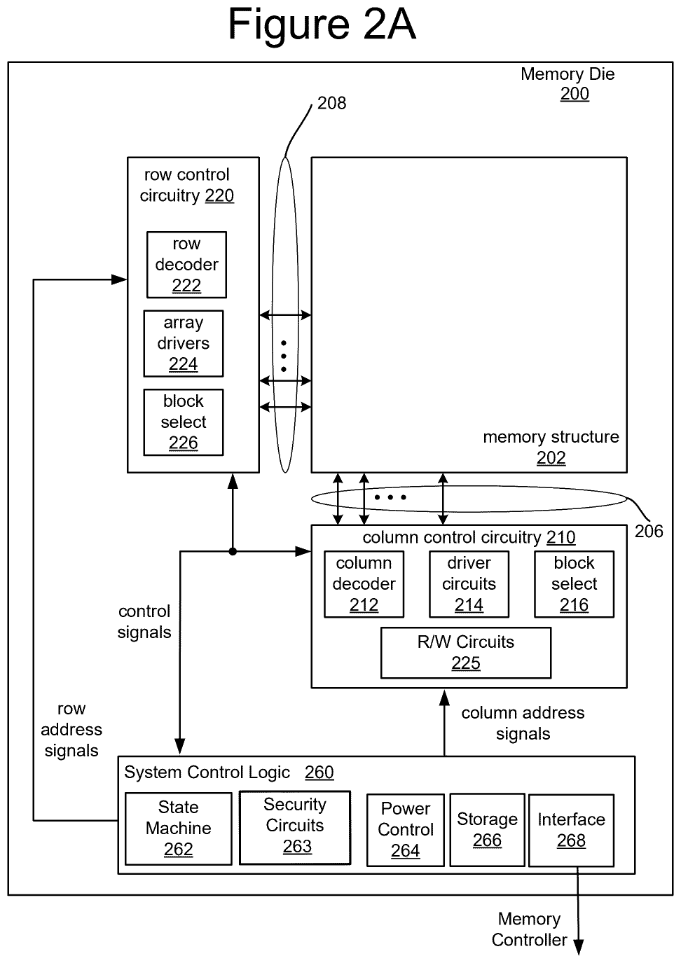

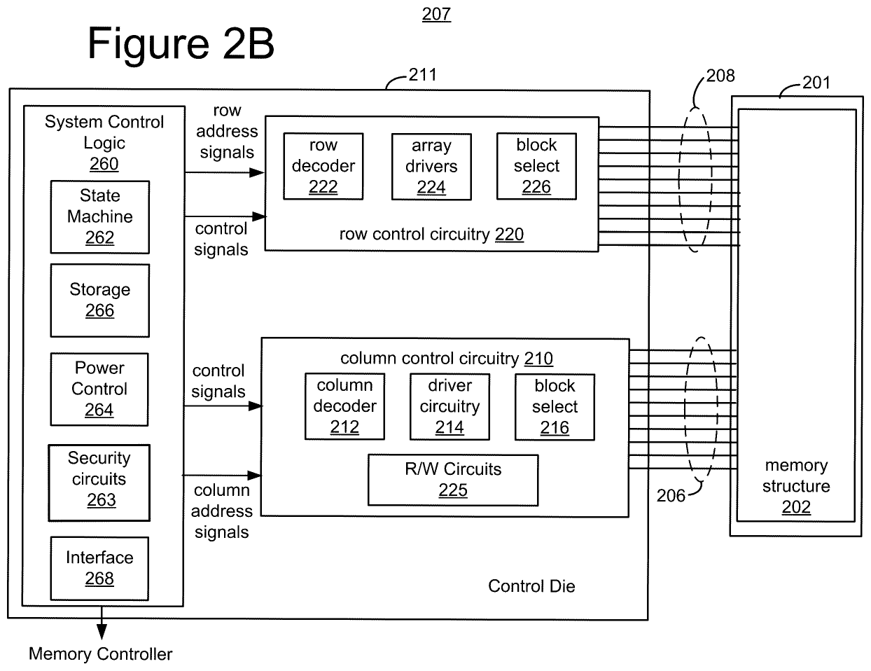

In one embodiment, nonvolatile storage 130 comprises one or more memory dies. FIG. 2A is a functional block diagram of one embodiment of a memory die 200 that comprises nonvolatile storage 130. Each of the one or more memory dies of nonvolatile storage 130 can be implemented as memory die 200 of FIG. 2A. The components depicted in FIG. 2A are electrical circuits. Memory die 200 includes a memory structure 202 (e.g., memory array) that can comprise nonvolatile memory cells (also referred to as nonvolatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic 260, and typically may include such circuits as row decoders 222, array drivers 224, and block select circuit 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for memory structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuit 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202. Security circuits 263 may provide security for data stored in memory structure 202 (e.g., limiting access to memory structure 202 to authorized users). Security circuits 263 may be in addition to security circuits 162. In other examples, security may be implemented at a single location (e.g., either by on-chip security circuits 263 of memory die 200 or by security circuits 162 in memory controller 120).

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of nonvolatile memory cells in which multiple memory levels are formed above a single substrate, such as a wafer. The memory structure may comprise any type of nonvolatile memory that are monolithically formed in one or more physical levels of memory cells having an active area disposed above a silicon (or other type of) substrate. In one example, the nonvolatile memory cells comprise vertical NAND strings with charge-trapping layers.

In another embodiment, memory structure 202 comprises a two-dimensional memory array of nonvolatile memory cells. In one example, the nonvolatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular nonvolatile memory technology is required for purposes of the new claimed embodiments proposed herein.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

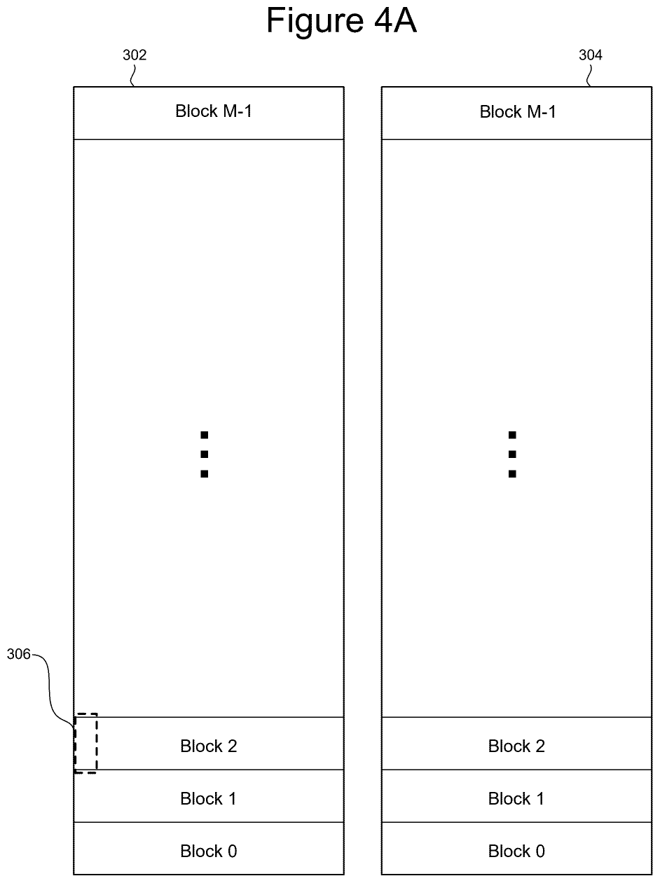

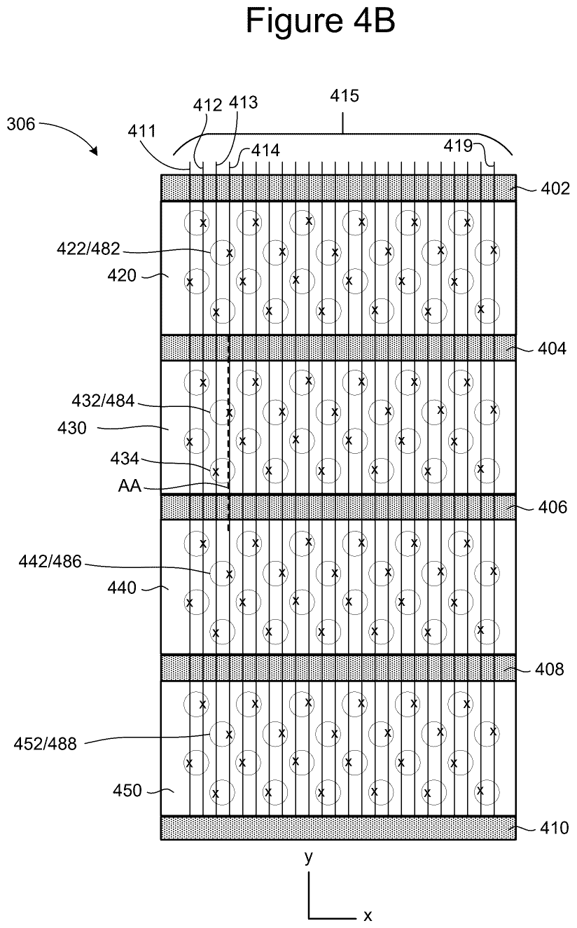

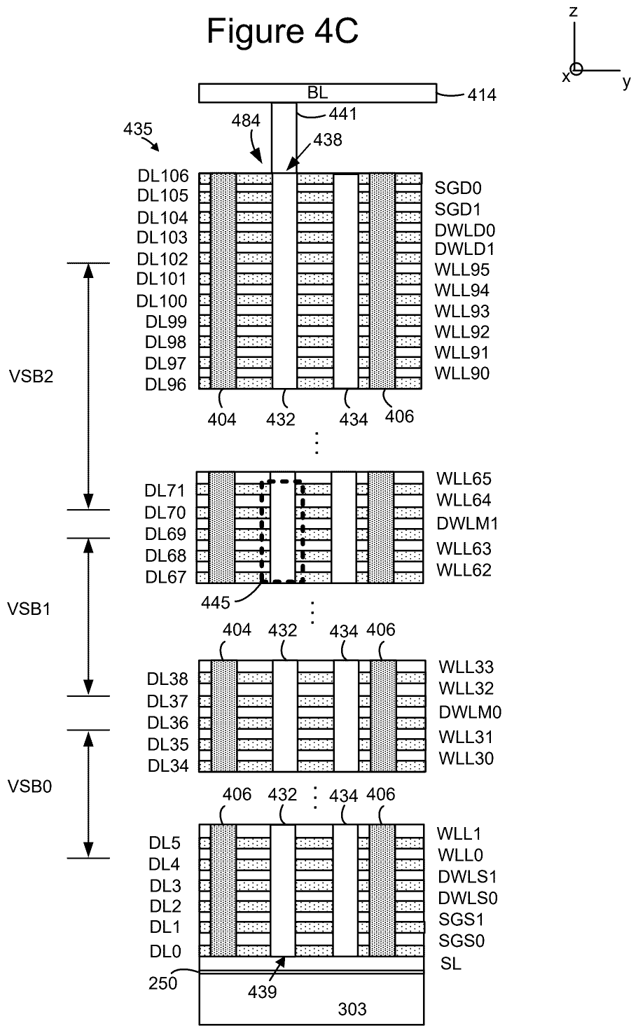

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the nonvolatile storage 130 of storage system 100. The integrated memory assembly 207 includes two types of semiconductor dies (or more succinctly, “die”). Memory structure die 201 includes memory structure 202. Memory structure 202 includes nonvolatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate memory controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuits 214, and block select circuit 216 and bit lines of memory structure 202. Electrical paths may extend from column control circuitry 210 in control die 211 through pads on control die 211 that are bonded to corresponding pads of the memory structure die 201, which are connected to bit lines of memory structure 202.

For purposes of this document, the phrases “a control circuit” or “one or more control circuits” can include any one of or any combination of memory controller 120, state machine 262, power control module 264, security circuits 263 all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, nonvolatile storage 130, memory die 200, integrated memory assembly 207, and/or control die 211.

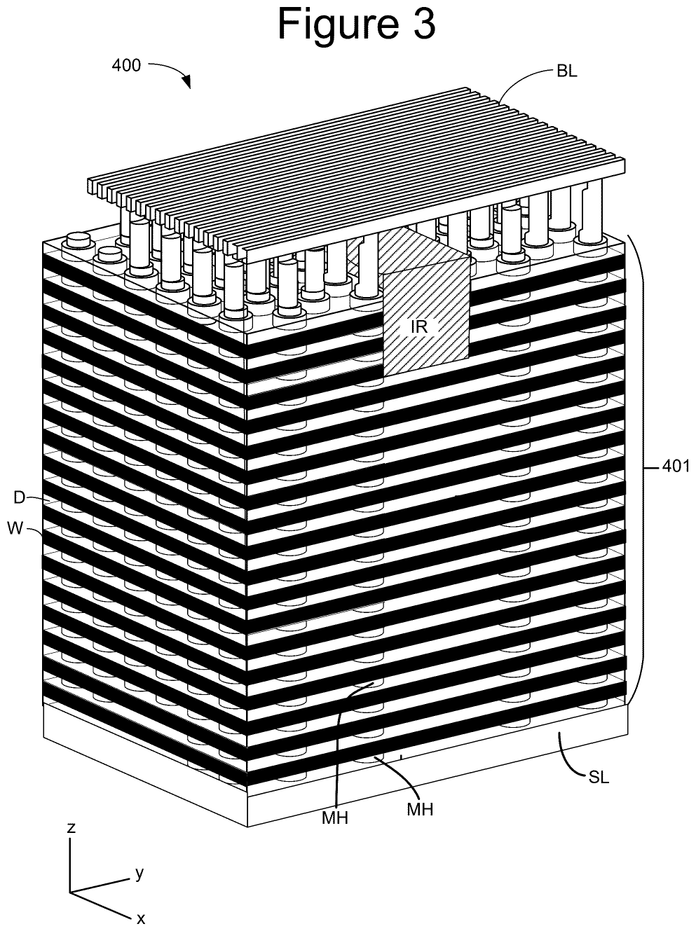

FIG. 3 is a perspective view of a portion of one example embodiment of a monolithic three dimensional memory array/structure that can comprise memory structure 202, which includes a plurality nonvolatile memory cells arranged as vertical NAND strings. For example, FIG. 3 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. In one embodiment the alternating dielectric layers and conductive layers are divided into four (or a different number of) regions (e.g., sub-blocks) by isolation regions IR. FIG. 3 shows one isolation region IR separating two sub-blocks. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data using two or more data states. More details of the three dimensional monolithic memory array that comprises memory structure 202 is provided below.

FIG. 4A is a block diagram explaining one example organization of memory structure 202, which is divided into two planes 302 and 304 (multi-plane structure). Each plane is then divided into M blocks. In one example, each plane has about 2000 blocks. However, different numbers of blocks and planes can also be used. In one embodiment, a block of memory cells is a unit of erase. That is, all memory cells of a block are erased together. Blocks may be erased one-by-one so that erasing a large number of blocks may take significant time and require significant energy. In other embodiments, memory cells can be grouped into blocks for other reasons, such as to organize the memory structure 202 to enable the signaling and selection circuits. In some embodiments, a block represents a groups of connected memory cells as the memory cells of a block share a common set of word lines.

FIGS. 4B-4C depict an example three dimensional (“3D”) NAND structure that corresponds to the structure of FIG. 3 and can be used to implement memory structure 202 of FIG. 2A or 2B. FIG. 4B is a block diagram depicting a top view of a portion of one block from memory structure 202. The portion of the block depicted in FIG. 4B corresponds to portion 306 in block 2 of FIG. 4A. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends beyond the portion shown, the block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the block is depicted. It is contemplated that more than twenty-four bit lines connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts an embodiment of a stack 435 showing a cross-sectional view along line AA of FIG. 4B. Two SGD layers (SGD0, SDG1), two SGS layers (SGS0, SGS1) and six dummy word line layers DWLD0, DWLD1, DWLM1, DWLM0, DWLS0 and DWLS1 are provided, in addition to the data word line layers WLL0-WLL95. Each NAND string has a drain side select transistor at the SGD0 layer and a drain side select transistor at the SGD1 layer. In operation, the same voltage may be applied to each layer (SGD0, SGD1), such that the control terminal of each transistor receives the same voltage. Each NAND string has a source side select transistor at the SGS0 layer and a drain side select transistor at the SGS1 layer. In operation, the same voltage may be applied to each layer (SGS0, SGS1), such that the control terminal of each transistor receives the same voltage. Also depicted are dielectric layers DL0-DL106.

Vertical columns 432, 434 of memory cells are depicted in the multi-layer stack. The stack includes a substrate 303, an insulating film 250 on the substrate, and a portion of a source line SL. A portion of the bit line 414 is also depicted. Note that NAND string 484 is connected to the bit line 414. NAND string 484 has a source-end 439 at a bottom of the stack and a drain-end 438 at a top of the stack. The source-end 439 is connected to the source line SL. A conductive via 441 connects the drain-end 438 of NAND string 484 to the bit line 414. The local interconnects 404 and 406 from FIG. 4B are also depicted.

The stack 435 is divided into three vertical sub-blocks (VSB0, VSB1, VSB2).

Vertical sub-block VSB0 includes WLL0-WLL31. The following layers could also be considered to be a part of vertical sub-block VSB0 (SGS0, SGS1, DWLS0, DWLS1). Vertical sub-block VSB1 includes WLL32-WLL63. Vertical sub-block VSB2 includes WLL64-WLL95. The following layers could also be considered to be a part of vertical sub-block VSB2 (SGD0, SGD1, DWLD0, DWLD1). Each NAND string has a set of data memory cells in each of the vertical sub-blocks. Dummy word line layer DMLM0 is between vertical sub-block VSB0 and vertical sub-block VSB1. Dummy word line layer DMLM1 is between vertical sub-block VSB1 and vertical sub-block VSB2. The dummy word line layers have dummy memory cell transistors that may be used to electrically isolate a first set of memory cell transistors within the memory string (e.g., corresponding with vertical sub-block VSB0 word lines WLL0-WLL31) from a second set of memory cell transistors within the memory string (e.g., corresponding with the vertical sub-block VSB1 word lines WLL32-WLL63) during a memory operation (e.g., an erase operation or a programming operation). Data stored in a 3D NAND memory may be erased (e.g., data states may be changed) by temperatures above 300 degrees centigrade and some other memory structure components may be affected by high temperature (e.g., aluminum melts at 660 degrees Celsius, copper at 1085 degrees and silicon at 1414 degrees).

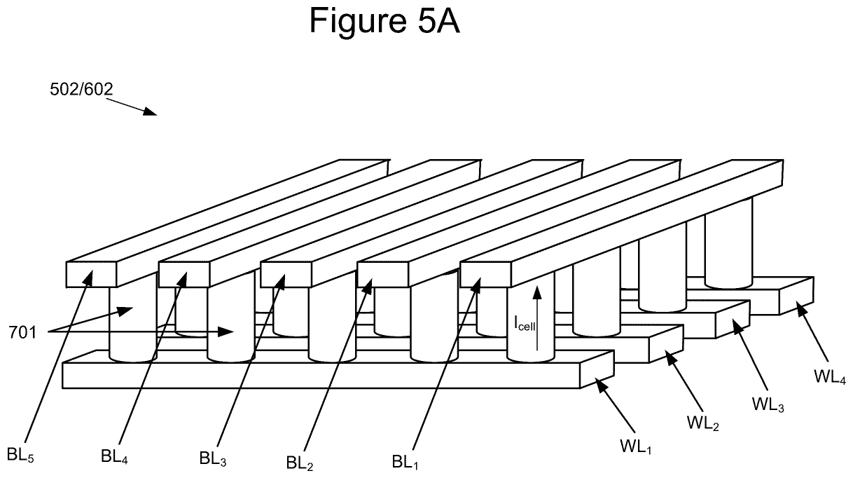

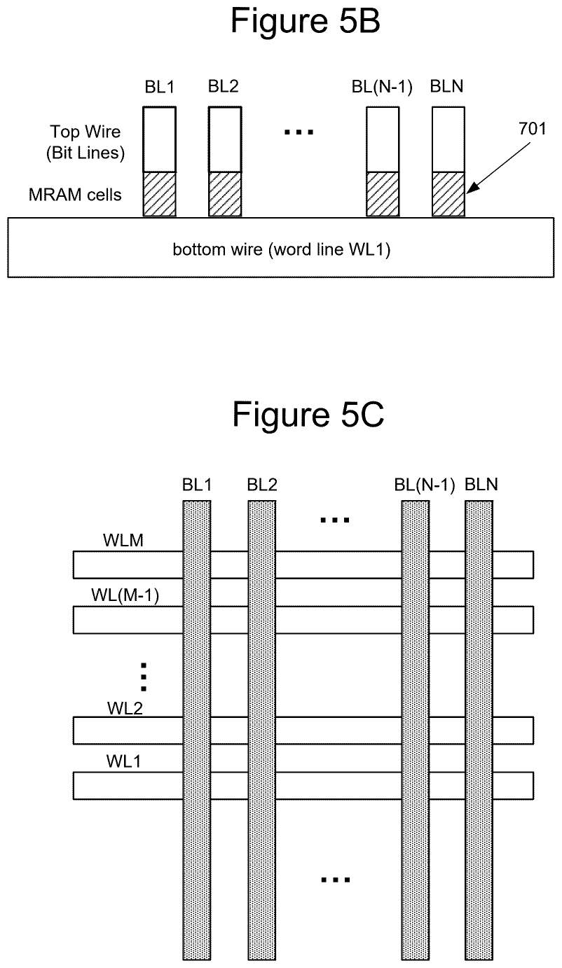

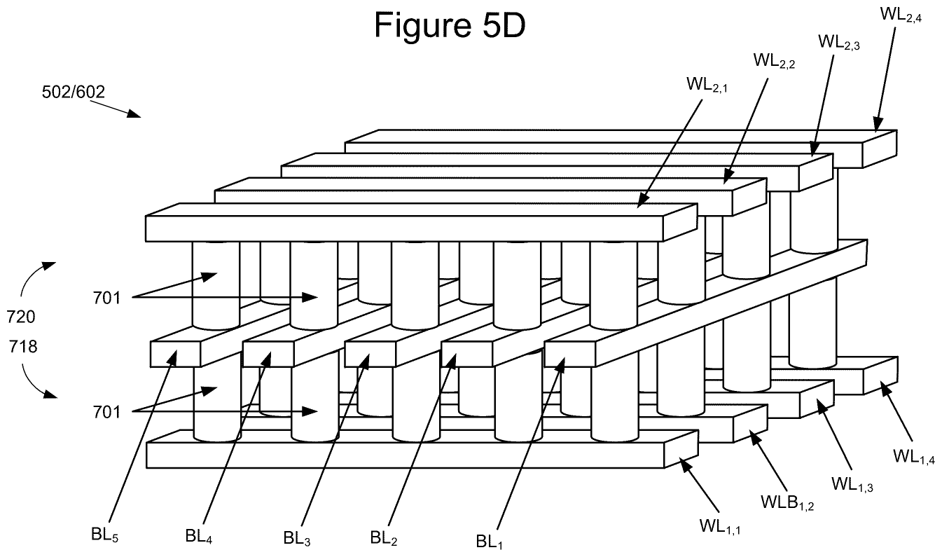

An alternative to the vertical NAND structure shown in FIGS. 3-4C is a cross-point memory structure. An example of a cross-point memory structure is shown in FIGS. 5A-D.

FIG. 5A depicts one embodiment of a portion of a memory structure (array) that forms a cross-point architecture in an oblique view. Memory structure 502/602 of FIG. 5A is one example of an implementation for a memory structure (e.g., memory structure 202), where a memory die can include multiple such array structures. The bit lines BL1-BL5 are arranged in a first direction (e.g., “bit line direction” represented as running into the page) relative to an underlying substrate (not shown) of the die and the word lines WL1-WL5 are arranged in a second direction (e.g., “word line direction”) perpendicular to the first direction (across the page). FIG. 5A is an example of a horizontal cross-point structure in which word lines WL1-WL5 and BL1-BL5 both run in a horizontal direction relative to the substrate, while the memory cells, two of which are indicated at 701, are oriented so that the current through a memory cell (such as shown at Icell) runs in the vertical direction. In a memory array with additional layers of memory cells, such as discussed below with respect to FIG. 5D, there would be corresponding additional layers of bit lines and word lines.

As depicted in FIG. 5A, memory array 502/602 includes a plurality of memory cells 701. The memory cells 701 may include re-writeable memory cells, such as can be implemented using ReRAM, MRAM, PCM, FeRAM, or other material with a programmable resistance. The current in the memory cells of the first memory level is shown as flowing upward as indicated by arrow Icell, but current can flow in either direction, as is discussed in more detail in the following.

FIGS. 5B and 5C respectively present side and top views of the cross-point structure in FIG. 5A. The sideview of FIG. 5B shows one bottom wire, or word line, WL1 and the top wires, orbit lines, BL1-BLn. At the cross-point between each top wire and bottom wire is an MRAM memory cell, although PCM, FeRAM, ReRAM, or other technologies can be used. FIG. 5C is a top view illustrating the cross-point structure for M bottom wires WL1-WLM and N top wires BL1-BLN. In a binary embodiment, the MRAM cell at each cross-point can be programmed into one of two resistance states: high and low (e.g., two data states).

The cross-point array of FIG. 5A illustrates an embodiment with one layer (one story) of word lines and bits lines, with the MRAM or other memory cells sited at the intersection of the two sets of conducting lines. To increase the storage density of a memory die, multiple layers (stories) of such memory cells and conductive lines can be formed. A 2-layer (2-story) example is illustrated in FIG. 5D.

FIG. 5D depicts an embodiment of a portion of a two level (two story) memory array that forms a cross-point architecture in an oblique view. As in FIG. 5A, FIG. 5D shows a first layer 718 (first story) of memory cells 701 of an array 502/602 connected at the cross-points of the first layer of word lines WL1,1-WL1,4 and bit lines BL1-BL5. A second layer (second story) of memory cells 720 is formed above the bit lines BL1-BL5 and between these bit lines and a second set of word lines WL2,1-WL2,4. Although FIG. 5D shows two layers (stories), 718 and 720, of memory cells, the structure can be extended upward through additional alternating layers of word lines and bit lines. Depending on the embodiment, the word lines and bit lines of the array of FIG. 5D can be biased for read or program operations such that current in each layer flows from the word line layer to the bit line layer or the other way around.

The use of a cross-point architecture allows for arrays with a small footprint and several such arrays can be formed on a single die. The memory cells formed at each cross-point can be a resistive type of memory cell, where data values are encoded as different resistance levels. Depending on the embodiment, the memory cells can be binary valued, having either a low resistance state or a high resistance state (two data states), or multi-level cells (MLCs) that can have additional resistance intermediate to the low resistance state and high resistance state (more than two data states).

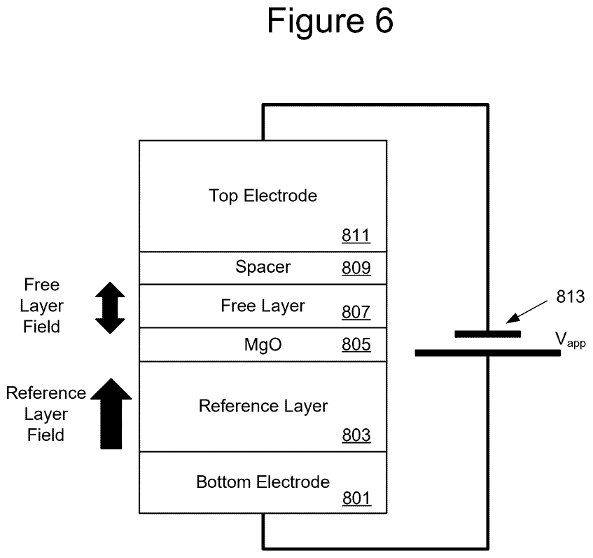

FIG. 6 illustrates an embodiment for the structure of an MRAM memory cell (e.g., any memory cell 701). A voltage being applied across the memory cell, between the memory cell's corresponding word line and bit line, is represented as a voltage source Vapp 813. The memory cell includes a bottom electrode 801, a pair of magnetic layers (e.g., reference layer 803 and free layer 807) separated by a separation or tunneling layer of, in this example, magnesium oxide (MgO) 805, and then a top electrode 811 separated from the free layer 807 by a spacer layer 809. The data state of the memory cell is based on the relative orientation of the magnetizations of the reference layer 803 and the free layer 807: if the two layers are magnetized in the same direction, the memory cell will be in a parallel (P) low resistance state (LRS); and if they have the opposite orientation, the memory cell will be in an anti-parallel (AP) high resistance state (HRS). An MLC embodiment would include additional intermediate data states. Reference layer 803 is also known as a fixed layer or pinned layer.

Data is written to an MRAM memory cell by programming the free layer 807 to either have the same orientation or opposite orientation. The reference layer 803 is formed so that it will maintain its orientation when programming the free layer 807. The reference layer 803 can have a more complicated design that includes synthetic anti-ferromagnetic layers and additional reference layers.

While aspects of the present technology may be implemented in 3D NAND flash memory (e.g., as illustrated in FIGS. 3-4C) or cross-point memory (e.g., as illustrated in FIGS. 5A-D) implemented by MRAM (e.g., as illustrated in FIG. 6), it is not limited to any particular memory structure and may be applied to other nonvolatile structures and memories such as ReRAM, PCM, FeRAM and volatile memories such as DRAM and SRAM.

In some cases, it may be desirable to destroy all data stored in a memory structure. Block-by-block erasing may be slow, require significant power and may not be appropriate in all situations. For example, in some military applications, it may be desirable to delete all data stored in a memory rapidly and securely in a situation where power may be removed (e.g., after an aircraft crashes). While external destructive devices (e.g., explosive) may be used in some cases, these may present safety concerns and may not be suitable for some applications (e.g., on aircraft or submarines where explosives may be particularly risky). It may be desirable to rapidly and safely erase all data stored in a memory without significantly impacting the surroundings (e.g., without an explosion, fire or other potentially dangerous effects).

Aspects of the present technology are directed to problems associated with erasing data stored in memory in a safe and rapid manner. Solutions may include locating one or more portions of energy-release material in a memory structure so that an energy-releasing (exothermic) reaction may be triggered that causes an increase in temperature sufficient to rapidly and safely erase all data stored in the memory structure.

Some materials that may be used as energy-release materials in a memory system may include a thermite, nano-thermite or thermate. A thermite is a composition (compound material) formed of metal powder and metal oxide, which when activated (e.g., by heating above a critical temperature, chemical reaction or otherwise) react together exothermically (releasing heat energy). Examples of thermite may include aluminum, magnesium, titanium, boron and zinc with an appropriate oxidizer such as bizmuth oxide, boron oxide, chromium oxide manganese oxide iron oxide, copper oxide or lead oxide. A nano-thermite is formed of thermite materials (e.g., as listed above) in small particles or powder (e.g., nanoparticles of under 100 nanometers). A thermate is composed of thermite enriched with a salt based oxidizer (e.g., a nitrate or peroxide). Thermite may reach 2500 degrees Celsius during energy-release and may provide sufficient heat energy to heat surrounding material accordingly. Ignition temperatures between 500 and 1300 degrees Celsius may be used to initiate energy-release.

Another example of an energy-release material is a metallic or metalloid multi-layer structure, which may be formed by alternating layers of suitable materials such as metals or metalloids. For example, an aluminum-nickel multilayered foil may be formed by alternately depositing aluminum and nickel (e.g., by sputtering), which may react to form NiAl in an exothermic reaction. Other examples of metallic and/or metalloid multi-layer materials includes alternating layers of aluminum and titanium, titanium and silicon (e.g., amorphous silicon), titanium and boron or aluminum and palladium.

When an energy-release material is activated (e.g., by heat or otherwise) an exothermic reaction occurs that releases heat energy. This release can heat additional portions of the energy-release material so that the reaction generates sufficient heat to propagate throughout a contiguous portion of material (e.g., once the material starts to “burn” it may continue until all the material is consumed). When a sufficient amount of energy-release material located in or near a memory structure is initiated, the temperature of the memory structure may rise sufficiently to erase the memory (e.g., temperature may rise above a threshold temperature that causes a change in one or more physical characteristic). For example, electrical, magnetic, resistive, structural and/or other properties of data storage materials may change in a manner that destroys data that is recorded in data storage material. By locating energy-release material in or near the memory structure, the high temperature effects may be limited to one or more dies or to the contents of an enclosure (e.g., a package) without significant effects on neighboring components (e.g., unlike an explosion or fire). This arrangement provides significant safety benefits. For example, such a memory structure may be included in components aboard aircraft, submarines or other sensitive locations without the risk associated with more destructive devices (e.g., explosive or incendiary devices).

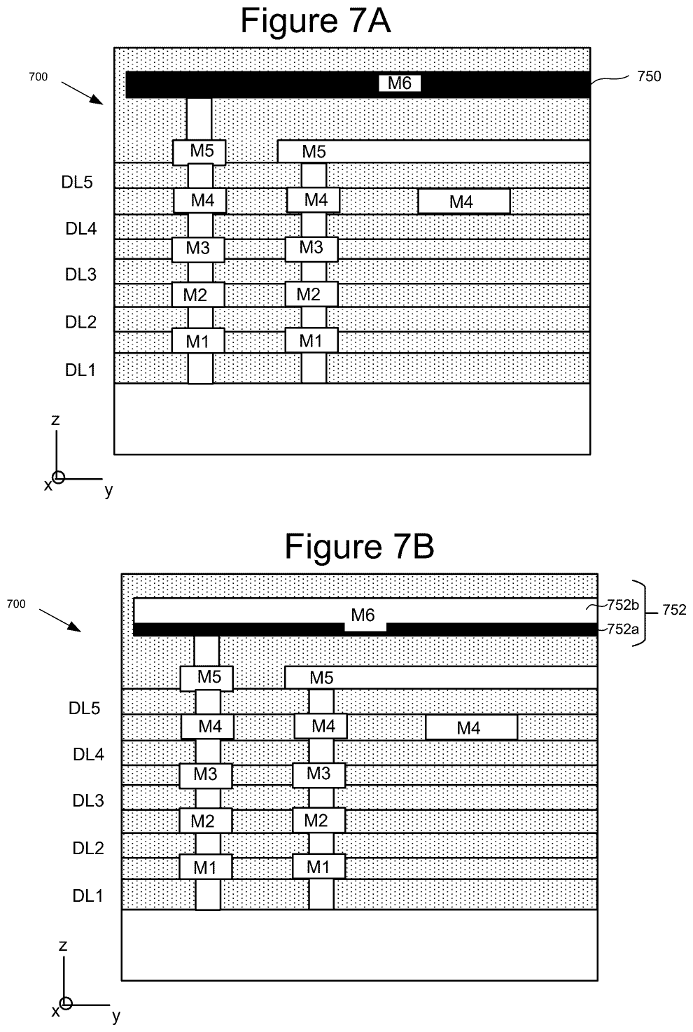

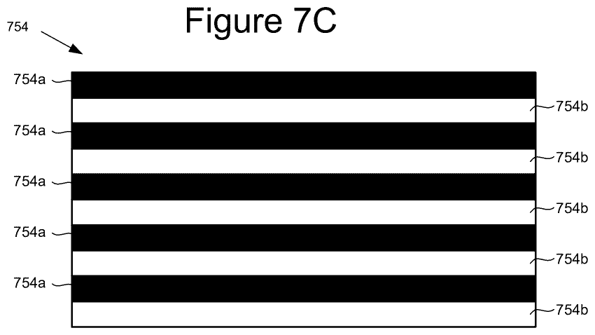

FIG. 7A shows an example of an energy-release material that is used to form an electrically conductive line 750 in a memory structure 700. While FIG. 7A shows a simplified memory structure with just six conductive metal layers (M1-M6), one of which (M6) is formed of energy-release material, in other examples more than six conductive layers may be provided and more than one such layer may be formed of energy-release material (e.g., two, three, four, five or all six layers M1-M6 may be formed of energy-release material). Locating an energy-release material in a higher layer as illustrated in FIG. 7A may have some benefits (e.g., little subsequent processing). In other examples, energy-release material may alternately/additionally be located in lower metal layers. Examples of energy-release materials that may be used in electrically conductive lines (e.g., conductive line 750) include various metallic multi-layer materials (e.g., aluminum-titanium, titanium-amorphous silicon, titanium-boron and aluminum-palladium).

In some cases, an energy-release material may be combined with one or more other material to form one or more conductive line in a memory structure. For example, FIG. 7B shows an example of conductive line 752, which is composed of a first layer of energy-release material 752a and a second layer of non-energy-release metal 752b (e.g., copper, aluminum, tungsten or other metal). By forming conductive lines of a combination of energy-release material and other material, the electrical properties of metal lines may be controlled (e.g., resistance may be reduced compared with forming a conductive line of energy-release material alone).

Energy-release material may be deposited in a manner that is compatible with process steps used to form a memory structure. For example, an energy-release material may be formed by depositing (e.g., by sputtering, ion beam deposition, e-beam deposition, thermal evaporation, chemical vapor deposition (CVD), molecular beam epitaxy, or other method) on a silicon wafer during a fabrication process. In an example, a metallic multi-layer material is formed by depositing alternating layers of different metals (e.g., nickel and aluminum). For example, nickel may be deposited by sputtering from a nickel target and aluminum may be deposited by sputtering from an aluminum target. FIG. 7C shows a portion of energy-release material 754, which is formed of alternating layers of a first metal 754a (e.g., nickel) and a second metal 754b (e.g., aluminum), which may be deposited over a substrate (e.g., to form conductive line 750 or energy-release material 752a of conductive line 752). First metal layers 754a may be formed by sputtering using a first target and second metal layers 754b may be formed by sputtering a second target (e.g., in different chambers). Patterning of energy-release material (e.g., energy-release material 754) may be performed so that energy-release material is located appropriately (e.g., energy-release material may be deposited as a blanket layer and subsequently patterned with unwanted energy-release material removed by etching, chemical mechanical polishing, or otherwise to leave separate conductive lines).

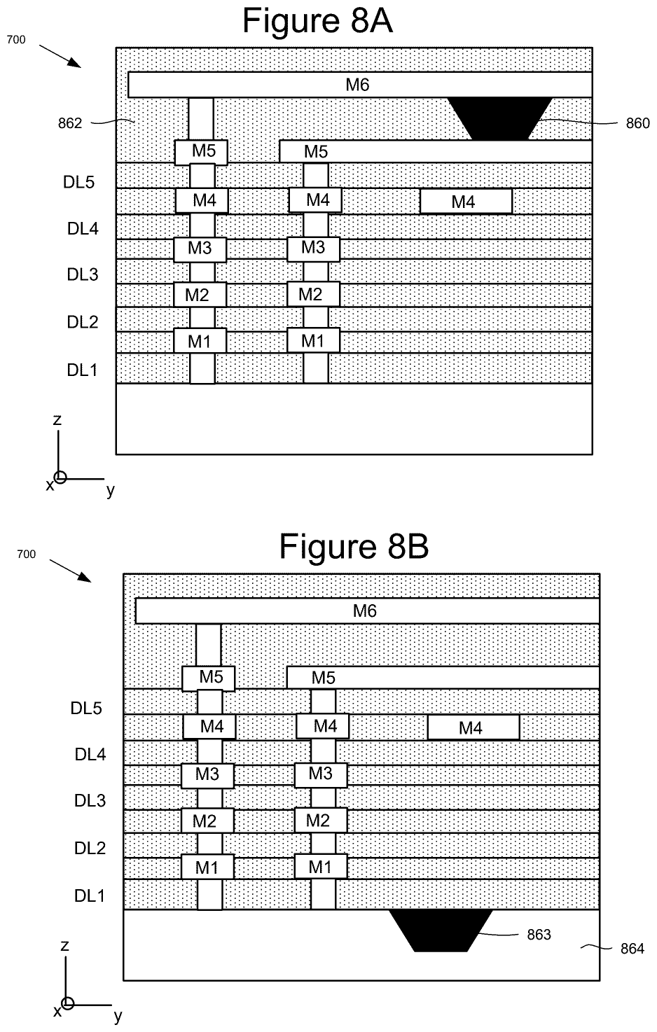

While FIGS. 7A-B show energy-release material located in a conductive line of a memory structure 700, the present technology is not limited to such a location. FIG. 8A shows an example in which a portion of energy-release material 860 is formed in the electrically insulating material 862 (dielectric) between electrically conductive lines of memory structure 700. For example, electrically insulating material 862 (e.g., silicon dioxide) is shown separating conductive lines of different metal layers (e.g., between M5 and M6) and between conductive lines of a given metal layer (e.g., between adjacent metal lines within M5 layer). Energy-release material 860 may be located in a trench or other opening formed in electrically insulating material 862. For example, after formation of electrically conductive lines of the M5 layer, electrically insulating material 862 may be deposited over the M5 conductive lines and one or more trenches may be formed (e.g., by patterning and etching) and filled with energy-release material. Subsequently, the M6 layer may be deposited and patterned to form M6 conductive lines. Energy-release material 860 is shown in contact with a conductive line of the M5 layer below and in contact with a conductive line of the M6 layer above. In this arrangement, triggering of energy-release material 860 may be initiated by applying appropriate conditions (e.g., a high voltage difference) through conductive lines of M5 and M6 layers. Energy-release material 860 may be a suitable material that is not electrically conductive so that the operation of conductive lines of M5 and M6 layers is not impacted (e.g., lines are not short circuited by energy-release material 860).

FIG. 8B shows energy-release material 863 located in substrate 864. For example, a trench or other opening may be formed in substrate 864 and energy-release material 863 may be deposited to fill such a trench. Subsequently, memory structure 700 may be formed over substrate 864 as shown.

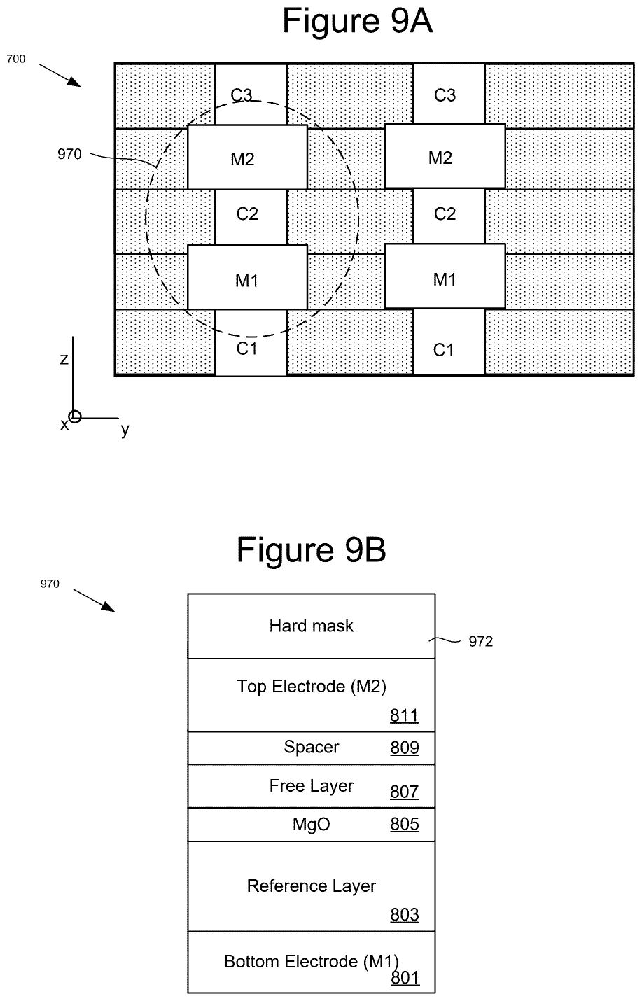

FIG. 9A illustrates a memory cell 970 formed in memory structure 700. Memory cell 970 includes a bottom electrode formed by a conductive line in the M1 metal layer and a top electrode formed by a conductive line in the M2 metal layer. Memory cell 970 is formed in a second layer of memory cells (C2 layer), which may include a large number of similar cells. In some examples, memory cells in one or more layers of memory cells may be configured to include energy-release material. For example, cells of the C2 layer and/or other layers may include energy-release material. Locating such material within memory cells may ensure that when energy-release occurs, the resulting energy is delivered within memory cells where it may be highly effective in causing physical changes that erase the memory cells.

Energy-release material may be located at any suitable location within a memory cell. The type of energy-release material and the location or locations selected may depend on the type of memory cell. FIG. 9B show an example memory cell structure for memory cell 970, which is similar to the structure of FIG. 6 and additionally includes a hard mask layer 972 that may be used to pattern memory cells (e.g., may define a pattern for etching material to separate memory cells). In the example of FIG. 9B, hard mask 972 is formed of an energy-release material (e.g., any of the examples discussed above). In other examples, one or more of bottom electrode 801, reference layer 803, MgO layer 805, free layer 807, spacer layer 809 or top electrode 811 may be formed of or may include energy-release material. The energy-release material may contain a magnetic compound, or be coupled closely to a magnetic compound, or be magnetic by itself. The magnetism may be made an integral part of a magnetic memory device (e.g., memory cell 970), which may stop functioning once the energy-release material has been activated.

An energy-release initiator may be connected to an energy-release material and may be configured to initiate an energy-release reaction in order to cause erase of stored data (e.g., by raising the temperature sufficiently to cause a physical change in a data storage material). For example, in some cases once an energy-release material is triggered by a suitable initiator, an exothermic reaction may produce enough energy to continue the reaction. Examples of energy-release initiators may include a resistive heater, a pyrotechnic initiator, a mechanical percussion system, a laser pulse, a friction initiator, chemical initiators or any other initiator that causes at least a portion of energy-release material to start an exothermic reaction (e.g., by reaching an ignition temperature).

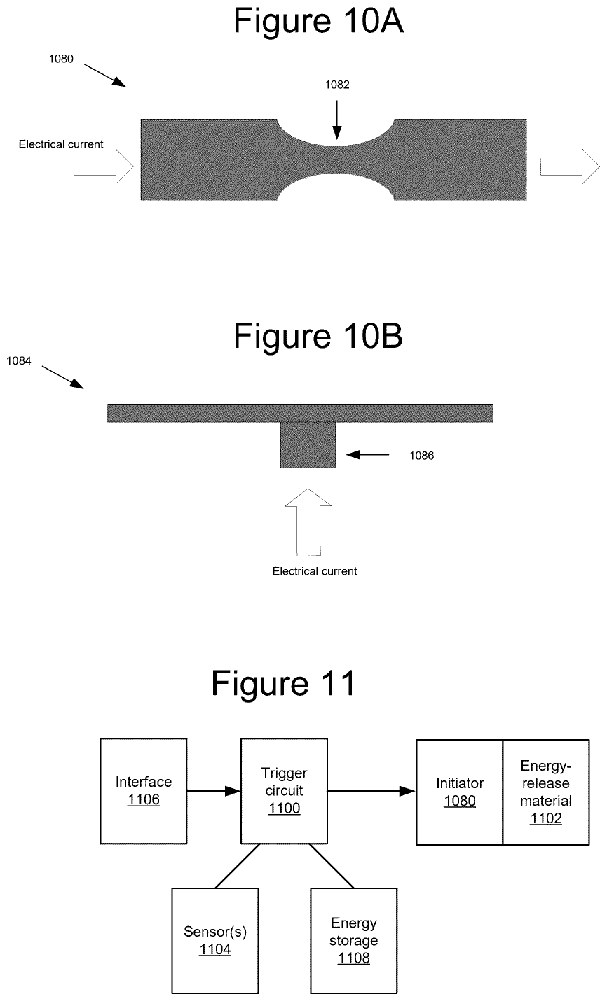

FIG. 10A shows an example of an energy-release initiator 1080 that is formed of a portion of material, which may be an energy-release material. Energy-release initiator 1080 includes a constriction 1082, which presents a small cross-sectional area to electrical current flowing as illustrated. The reduced cross-sectional area results in increased resistance and may result in significant resistive heating. For example, when a sufficient electrical current passes through initiator 1080, resistive heating at constriction 1082 may result in a temperature that is sufficient to initiate an energy-release material (e.g., above an initiation temperature sufficient to trigger an exothermic reaction of the energy-release material). Where initiator 1080 is formed of energy-release material the energy-release material may subsequently release enough energy to continue reacting. In an example, initiator 1080 is formed of a material that is not an energy-release material and is located adjacent (e.g., in physical contact with) an energy-release material. Initiator 1080 may raise the temperature of an adjacent energy-release material (e.g., initiator 1080 may act as a resistive heater) sufficiently to initiate an exothermic reaction which then propagates as a result of the energy released.

FIG. 10B shows an example of an initiator 1084 in which current flows vertically through a constriction 1086, which may be formed, for example, between metal layers in a multi-layer memory structure. Initiator 1084 may operate similarly to initiator 1080, with constriction 1086 reaching a high temperature when a sufficient current is passed and the high temperature initiating an exothermic reaction in an energy-release material.

In some cases, an initiator (e.g., initiator 1080 or 1084) may be connected to a pad or pin of a die to allow a suitable voltage to be applied to cause triggering and initiation of an energy-release material (e.g., when a high voltage is applied on a certain pin, current flow through initiator 1080 or 1084 causes initiation temperature that initiates energy-release).

In some examples, an energy-release trigger circuit may be connected to the energy-release initiator. The energy-release trigger circuit may be configured to cause the energy-release initiator to achieve the initiation temperature in response to an electrical signal such as a digital signal or code or in response to detection of certain conditions. For example, a logic circuit may trigger energy-release in response to a triggering event such as receipt of a digital code (e.g., a self-destruct code or command), failure to receive a digital code (e.g., failure of authentication by a party attempting access), receipt of an analog voltage on a pin or pad on the memory die (e.g., a voltage on a dedicated pin or pad), detection of a breach of an enclosure around the memory die (e.g., detection of light, air or other change within the enclosure that indicates breach of an enclosure), detection of acceleration above a threshold (e.g., one or more accelerometers may indicate a force above a threshold such as associated with an aircraft crash) detection of an unauthorized location (e.g., by GPS or otherwise), detection of power loss or other triggering event that may be configured in hardware, programmable logic and/or software.

FIG. 11 illustrates an example of an energy-release trigger circuit 1100 connected to energy-release initiator 1080, with energy-release trigger circuit 1100 configured to cause energy-release initiator 1080 to achieve an initiation temperature of energy-release material 1102 in response to a triggering event. Trigger circuit 1100 is connected to sensor(s) 1104 and a triggering event may be detection of some conditions via sensor(s) 1104. For example, sensor(s) 1104 may include one or more accelerometer and a triggering event may be acceleration (including negative acceleration or deceleration) greater than a threshold. Sensor(s) 1104 may include position sensor(s) such as GPS location sensors and a triggering event may be a location outside a predetermined perimeter (e.g., an authorized area) or a location within a predetermined perimeter (e.g., an unauthorized area). Sensor(s) may include an altimeter and a triggering event may include an altitude above or below a predetermined level.

FIG. 11 shows trigger circuit 1100 connected to interface 1106 (e.g., interface 268 or host interface 152). Trigger circuit 1100 may detect a triggering event via interface 1106. For example, receipt of a command (e.g., a digital code) via interface 1106 may cause trigger circuit 1100 to trigger initiator 1080. Trigger circuit may be connected to or form part of security circuits of a memory system (e.g., security circuits 162 in memory controller 120 and/or security circuits 263) and a triggering event may be related to a security system. For example, a security system may require authentication in order to access a memory structure and failure of such authentication (e.g., receipt of an incorrect code or failure to receive an appropriate code) may be a triggering event.

FIG. 11 shows energy storage 1108 connected to trigger circuit 1100. Energy storage 1108 may provide sufficient energy for trigger circuit 1100 to operate in case of loss of external power. For example, energy storage 1108 may be a battery, isotope battery, capacitor or other device with sufficient energy (e.g., electrical and/or chemical energy) stored to enable trigger circuit 1100 to trigger initiator 1080 (e.g., to apply a sufficient current to cause initiator to reach a sufficient temperature to initiate energy-release material 1102). Energy storage 1108 may be located in the same die as trigger circuit 1100 (e.g., in memory controller 120, memory die 200 or control die 211) so that power remains available to trigger circuit 1100 even when external power is lost. Energy-release material 1102 and initiator 1080 may be located in one or more layers of a memory die (e.g., memory die 200 or 201). Trigger circuit 1100, sensor(s) 1104, energy storage 1108 and interface 1106 may be located in the memory die or on one or more other die (e.g., control die 211 and/or in memory controller 120). In an example, trigger circuit 1100 may be connected to initiators in multiple memory dies (e.g., each memory die in a package may include a separate initiator, with a single trigger circuit to initiate energy-release in different memory dies individually or together). Sufficient energy-release material may be provided to achieve a temperature above a threshold temperature for erasing a data storage material. Energy-release material 1102 (alone or in combination with initiator 1080 and/or trigger circuit 1100) may be considered an example of means for exothermically reacting an energy-release material in the memory die with sufficient energy to change programmed data states of the plurality of memory cells.

In some cases, erasing of one or more memory dies may be achieved without obvious outward indications (e.g., heating may be relatively brief and generally limited to one or more die or package). In order to be able to determine when a die, package or other unit has been successfully erased, some erase-indicator may be provided. In some cases, it may be possible to electrically determine if erase has occurred (e.g., electrical discontinuity of an electrical initiator may indicate erasure has occurred). In some cases, a visible erase-indicator of erase may be provided.

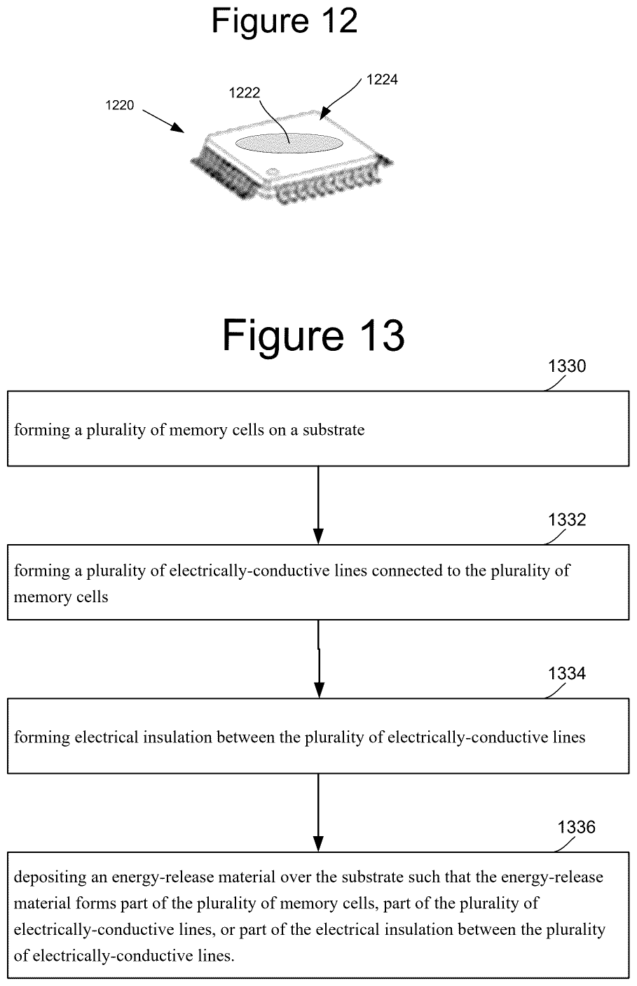

FIG. 12 shows an example of a package 1220 that may include one or more memory die in an enclosure (e.g., enclosure formed of plastic, ceramic or other suitable material). Package 1220 includes a visible erase-indicator 1222 on an outer surface (top surface 1224). For example, visible erase-indicator 1222 may consist of or include a heat-activated material that changes appearance at a temperature above a certain temperature. When energy-release material is activated in a die in package 1220, energy-release may cause the temperature of heat-activated material to change, thereby providing a visible erase-indicator that the memory die is erased (e.g., spelling out “ERASED” or other such word or symbol). Such a visible erase-indicator may provide confirmation that sensitive material is safely destroyed and can no longer be accessed. While visible erase-indicator 1222 is shown on the outside of a package, in other cases, a window may be provided in a package and a visible erase-indicator may be located within the package (e.g., on the surface of a die) where it is visible through the window. A visible erase-indicator may also assist troubleshooting in the case where die erase is suspected. In some cases, a visible erase-indicator may be in the form of a holographic optical element, a diffractive optical element, or an optically variable image device that may additionally provide authentication that a product is not counterfeit or has not been tampered with. The activation of heat-activated material may destroy or alter the visual effect produced by such an element.

FIG. 13 illustrates an example of a method that may be implemented in a memory system to safely erase all data stored in a memory structure. The method includes forming a plurality of memory cells on a substrate 1330 (e.g., forming memory cells in NAND strings on substrate 303 as shown in FIG. 4C or forming memory cells 701 as shown in FIGS. 5A-D), forming a plurality of electrically-conductive lines connected to the plurality of memory cells 1332 (e.g., word lines and bit lines) and forming electrical insulation between the plurality of electrically-conductive lines 1334 (e.g., DL0 to DL 106 of FIG. 4C or insulating material 882 of FIG. 8A). The method further includes, depositing an energy-release material over the substrate such that the energy-release material forms part of the plurality of memory cells (e.g., FIGS. 9A-B), part of the plurality of electrically-conductive lines (e.g., FIGS. 7A-B), or part of the electrical insulation between the plurality of electrically-conductive lines (e.g., FIG. 8A).

An example of a memory structure on a substrate includes electrically conductive lines connected to memory cells with electrically insulating material between adjacent electrically conductive lines. The memory structure includes an energy-release material in at least one of the electrically conductive lines, the memory cells, the electrically insulating material or the substrate.

In one or more embodiments, the memory structure further includes an energy-release initiator connected to the energy-release material, the energy-release initiator configured to achieve an initiation temperature sufficient to trigger an exothermic reaction of the energy-release material.

In one or more embodiments, the memory structure further includes an energy-release trigger circuit connected to the energy-release initiator, the energy-release trigger circuit configured to cause the energy-release initiator to achieve the initiation temperature in response to an electrical signal.

In one or more embodiments, the memory structure further includes an energy storage connected to the energy-release trigger circuit, the energy storage configured to power the energy-release initiator.

In one or more embodiments, the energy-release material is a metallic multi-layer material that forms at least part of one or more of the electrically conductive lines.

In one or more embodiments, the metallic multi-layer material includes alternating layers of nickel and aluminum, aluminum and titanium, titanium and amorphous silicon, titanium and boron or aluminum and palladium.

In one or more embodiments, the energy-release material is located in a trench formed in the substrate or in the electrically insulating material.

In one or more embodiments, the energy-release material is thermite, nano-thermite or thermate.

In one or more embodiments, the energy-release material is located in the memory cells.

In one or more embodiments, the memory structure further includes a heat-activated erase-indicator on a surface of an enclosure that includes the substrate, the heat-activated erase-indicator configured to change appearance at a temperature generated by energy-release material.

An example of a method includes forming a plurality of memory cells on a substrate; forming a plurality of electrically-conductive lines connected to the plurality of memory cells; forming electrical insulation between the plurality of electrically-conductive lines; and depositing an energy-release material over the substrate such that the energy-release material forms part of the plurality of memory cells, part of the plurality of electrically-conductive lines, or part of the electrical insulation between the plurality of electrically-conductive lines.

In one or more embodiments, depositing the energy-release material includes depositing alternating layers of a first material and a second material.

In one or more embodiments, the first and second materials are aluminum and titanium, titanium and silicon, titanium and boron or aluminum and palladium.

In one or more embodiments, depositing the energy-release material includes alternately sputtering the first material from a first sputtering target and sputtering the second material from a second sputtering target.

In one or more embodiments, depositing the energy-release material includes depositing a blanket layer of energy-release material and subsequently removing portions of the energy-release material according to a pattern.

In one or more embodiments, depositing the energy-release material includes depositing thermite, nano-thermite or thermate in trenches in the substrate or the electrical insulation.

In one or more embodiments, the method further includes forming a heat-activated erase-indicator on a surface of an enclosure that includes the substrate.

An example of a data storage system includes a memory die that includes a plurality of memory cells configured to store data in two or more programmed data states; and means for exothermically reacting an energy-release material in the memory die with sufficient energy to change programmed data states of the plurality of memory cells, the means for exothermically reacting located in one or more layer of the memory die.

In one or more embodiments, the data storage system further includes an energy-release initiator connected to the means for exothermically reacting, the energy-release initiator configured to achieve an initiation temperature sufficient to trigger the means for exothermically reacting; and an energy-release trigger circuit connected to the energy-release initiator, the energy-release trigger circuit configured to cause the energy-release initiator to achieve the initiation temperature in response to a triggering event.

In one or more embodiments, the energy-release trigger circuit is configured to cause the energy-release initiator to achieve the initiation temperature in response to one or more triggering event including at least one of: receipt of a digital code, failure to receive a digital code, receipt of an analog voltage on a pin or pad on the memory die, detection of a breach of an enclosure around the memory die, detection of acceleration above a threshold, detection of an unauthorized location or detection of power loss.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A memory structure formed on a substrate, the memory structure including electrically conductive lines connected to memory cells with electrically insulating material between adjacent electrically conductive lines, the memory structure including an energy-release material in at least one of the electrically conductive lines, the memory cells, the electrically insulating material or the substrate.

2. The memory structure of claim 1, further comprising an energy-release initiator connected to the energy-release material, the energy-release initiator configured to achieve an initiation temperature sufficient to trigger an exothermic reaction of the energy-release material.

3. The memory structure of claim 2, further comprising an energy-release trigger circuit connected to the energy-release initiator, the energy-release trigger circuit configured to cause the energy-release initiator to achieve the initiation temperature in response to an electrical signal.

4. The memory structure of claim 3, further comprising an energy storage connected to the energy-release trigger circuit, the energy storage configured to power the energy-release initiator.

5. The memory structure of claim 1, wherein the energy-release material is a multi-layer material that forms at least part of one or more of the electrically conductive lines.

6. The memory structure of claim 5, wherein the multi-layer material includes layers of two or more of nickel, aluminum, titanium, amorphous silicon, boron and palladium or alloys thereof.

7. The memory structure of claim 1, wherein the energy-release material is located in a trench formed in the substrate or in the electrically insulating material.

8. The memory structure of claim 7, wherein the energy-release material is thermite, nano-thermite or thermate.

9. The memory structure of claim 1, wherein the energy-release material is located in the memory cells.

10. The memory structure of claim 1, further comprising a heat-activated erase-indicator on a surface of an enclosure that includes the substrate, the heat-activated erase-indicator configured to change appearance at a temperature generated by energy-release material.

11. A method comprising:
forming a plurality of memory cells on a substrate;
forming a plurality of electrically-conductive lines connected to the plurality of memory cells;
forming electrical insulation between the plurality of electrically-conductive lines; and
depositing an energy-release material over the substrate such that the energy-release material forms part of the plurality of memory cells, part of the plurality of electrically-conductive lines, or part of the electrical insulation between the plurality of electrically-conductive lines.

12. The method of claim 11, wherein depositing the energy-release material includes depositing alternating layers of a first material and a second material.

13. The method of claim 12, wherein the first and second materials are nickel and aluminum, aluminum and titanium, titanium and silicon, titanium and boron or aluminum and palladium.

14. The method of claim 12, wherein depositing the energy-release material includes alternately sputtering the first material from a first sputtering target and sputtering the second material from a second sputtering target.

15. The method of claim 11, wherein depositing the energy-release material includes depositing a blanket layer of energy-release material and subsequently removing portions of the energy-release material according to a pattern.

16. The method of claim 11, wherein depositing the energy-release material includes depositing thermite, nano-thermite or thermate in trenches in the substrate or the electrical insulation.

17. The method of claim 11, further comprising forming a heat-activated erase-indicator on a surface of an enclosure that includes the substrate.

18. A data storage system comprising:
a memory die that includes a plurality of memory cells configured to store data in two or more programmed data states; and
means for exothermically reacting an energy-release material in the memory die with sufficient energy to change programmed data states of the plurality of memory cells, the means for exothermically reacting located in one or more layer of the memory die.

19. The data storage system of claim 18, further comprising:
an energy-release initiator connected to the means for exothermically reacting, the energy-release initiator configured to achieve an initiation temperature sufficient to trigger the means for exothermically reacting; and
an energy-release trigger circuit connected to the energy-release initiator, the energy-release trigger circuit configured to cause the energy-release initiator to achieve the initiation temperature in response to a triggering event.

20. The data storage system of claim 19, wherein the energy-release trigger circuit is configured to cause the energy-release initiator to achieve the initiation temperature in response to one or more triggering event including at least one of: receipt of a digital code, failure to receive a digital code, receipt of an analog voltage on a pin or pad on the memory die, detection of a breach of an enclosure around the memory die, detection of acceleration above a threshold, detection of an unauthorized location or detection of power loss.
